(19) United States
(12) Patent Application Publication
(10) Pub. No.: US 2009/0314330 A1
(43) Pub. Date: Dec. 24, 2009

(54) PHOTOVOLTAIC MODULE

(75) Inventors: Ivan Saha, Chennai (IN); Amitabh Verma, Chennai (IN)

Correspondence Address: DARBY & DARBY P.C., P.O. BOX 770, Church Street Station, New York, NY, 10008-0770, US

(73) Assignee: MOSER BAER PHOTOVOLTAIC LIMITED, Chennai (IN)

(21) Appl. No.: 12/182,268

(22) Filed: Jul. 30, 2008

(30) Foreign Application Priority Data
Jun. 24, 2008 (IN) 2008/CHE/007138

(51) Int. Cl. H01L 31/042

(52) U.S. Cl. 136/246

(57) ABSTRACT

Methods and systems for fabricating a photovoltaic module are provided. One or more stiffeners are integrated with a base substrate for stiffening the base substrate. One or more photovoltaic strips are arranged over the base substrate, such that spaces are formed between adjacent photovoltaic strips. The photovoltaic strips are connected through one or more conductors in a predefined manner. A plurality of optical vees are placed in the spaces between the photovoltaic strips for concentrating solar energy over the photovoltaic strips.

### CROSS REFERENCE TO RELATED APPLICATIONS

This application claims the benefit of Indian Patent Application Number 2008/CHE/007138, filed on Jun. 24, 2008, which is hereby incorporated by reference in its entirety.

### BACKGROUND

The present invention relates, in general, to photovoltaic modules. More specifically, the present invention relates to a method of stiffening a base substrate of a photovoltaic module.

Photovoltaic cells are large area semiconductor diodes that convert incident solar energy into electrical energy. Photovoltaic cells are often made of silicon wafers. The photovoltaic cells are combined in series and/or parallel to form photovoltaic modules.

Concentrator photovoltaic modules have been used to generate higher power outputs from the solar energy. The concentrator photovoltaic modules provide higher power output per unit area of photovoltaic surface as compared to conventional flat panel photovoltaic modules. Base panel of large-sized concentrator photovoltaic modules tend to warp or deform during fabrication or usage at high temperatures. For example, the base panel tends to warp during lamination of photovoltaic module.

Various methods have been used to reduce the warpage and deformation in the photovoltaic modules. For example, multiple photovoltaic sub-modules are joined together to form a large photovoltaic module. However, such methods add various overheads, such as assembling of sub-modules, and thus increase the cost of manufacturing the photovoltaic modules. Further, these methods do not provide thermal conductive base panel that can dissipate the heat inside the photovoltaic module. The photovoltaic module may be exposed to excessive heat during fabrication or usage of photovoltaic module at high temperatures. Absence of thermally conductive base panel leads to additional warpage in the photovoltaic module.

In light of the foregoing discussion, there is a need for a photovoltaic module (and a fabrication method and system thereof) that is suitable for mass manufacturing, has rigid and thermally conductive base panel, uses lesser amount of material, has lesser weight, and has lower cost, compared to conventional low concentrator photovoltaic modules.

### SUMMARY

An object of the present invention is to provide a photovoltaic module that has high rigidity and lesser weight, while using lesser amount of material, compared to conventional low concentrator photovoltaic modules.

Another object of the present invention is to provide the photovoltaic module that is suitable for mass manufacturing, compared to conventional low concentrator photovoltaic modules.

Yet another object of the present invention is to provide the photovoltaic module that has lower cost, compared to conventional low concentrator photovoltaic modules.

Embodiments of the present invention provide a photovoltaic module for generating electricity from solar energy. The photovoltaic module includes a base substrate for providing a support to the photovoltaic module. One or more stiffeners are integrated with the base substrate for stiffening the base substrate. Stiffeners provide support to the base substrate and avoid any warpage or deformation during the fabrication of the photovoltaic module. In an embodiment of the present invention, the stiffeners may be attached with at least one surface of the base substrate. In another embodiment of the present invention, the base substrate and the stiffeners are integrated in a composite form. Examples of the stiffeners include, but are not limited to, wires, strips, sheets, rods, granules and fibers. In accordance with an embodiment of the present invention, the stiffeners are made of a thermally-conductive material, and provide high thermal conductivity to the base substrate of the photovoltaic module.

One or more photovoltaic strips are arranged over the base substrate in a predefined manner. The predefined manner may, for example, be a series and/or parallel arrangement, such that electrical output is maximized. The photovoltaic strips may be formed by dicing a semiconductor wafer. The photovoltaic strips are arranged with spaces in between adjacent photovoltaic strips. The photovoltaic strips are connected through one or more conductors in series and/or parallel.

A plurality of optical vees are placed in the spaces between the photovoltaic strips, such that a plurality of cavities are formed between adjacent optical vees. The optical vees are capable of concentrating solar energy over the photovoltaic strips. In an embodiment of the present invention, the plurality of cavities formed between adjacent optical vees forms a trapezoidal shape in cross-section. The optical vees may be hollow or solid.

In an embodiment of the present invention, the optical vees include a reflective layer such that rays incident on the reflective layer are reflected towards photovoltaic strips. When the reflected sun rays fall on the photovoltaic strips, electricity is generated by the photoelectric effect. These optical vees may, for example, be made of glass, plastics, polymeric materials, Ethyl Vinyl Acetate (EVA), Thermoplastic Poly-Urethane (TPU), Poly Vinyl Butyral (PVB), silicone, acrylics, polycarbonates, metals, metallic alloys, metal compounds, and ceramics. In accordance with an embodiment of the present invention, the optical vees comprise a reflection-enhancing layer to enhance the reflectivity of the optical vees.

In another embodiment of the present invention, the optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. The optical vees may, for example, be made of glass, plastics, and acrylics.

In an embodiment of the present invention, one or more concentrating elements are introduced for concentrating solar energy over photovoltaic strips. The concentrating elements are formed by introducing a polymeric material in a fluid state over the photovoltaic strips and the optical vees, such that the polymeric material fills the cavities between the optical vees and take the shape of the cavities in cross-section. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylic, polycarbonates, and synthetic resins. In an embodiment of the present invention, concentrating elements form a trapezoidal shape in cross-section. The concentrating elements are optically coupled to the photovoltaic strips. Space or air bubble left between the concentrating elements and the optical vees, and between the concentrating elements and the photovoltaic strips which minimizes optical defects.

A medium boundary is formed at the interface of the first medium and the second medium, at a predefined angle, such that rays incident within an angular limit of normal to the base substrate are total internally reflection at the medium boundary and fall on the photovoltaic strips. In this way, electromagnetic radiation falling on the concentrating elements is concentrated over the photovoltaic strips. In order to increase the efficiency of concentration, various parameters, such as the refractive indices of the optical vees and the concentrating elements, may be manipulated. In an embodiment of the present invention, filling of the cavities with the polymeric material is done by moulding the polymeric material to form the concentrating elements. During moulding of the concentrating elements, the extra volume of the polymeric material forms a layer of the polymeric material over the concentrating elements and the optical vees. In this embodiment, the layer protects the photovoltaic module from environmental damages. Further, the layer of the polymeric material may be coated with an anti-reflective coating to reduce loss of solar energy incident on the photovoltaic module. In such a case, no reflection occurs at the surface of the concentrating elements, thereby increasing the efficiency of concentration. Further, no refraction occurs at a medium boundary between the optical vees and the concentrating elements, when the refractive index of the optical vees is equal to the refractive index of the moulded concentrating elements. In such a case, the medium boundary between the optical vees and the concentrating elements is optically transparent. The refractive indexes of the concentrating elements and the optical vees are more than the refractive index of air or vacuum.

In an embodiment of the present invention, the photovoltaic module also includes a transparent member positioned over the optical vees. The transparent member is coated with an anti-reflective coating to reduce loss of solar energy incident on the photovoltaic module. The transparent member is sealed with the base substrate.

The stiffeners provide high rigidity to the photovoltaic module, with lesser weight and lesser amount of material, compared to conventional low concentrator photovoltaic modules.

The fabrication of the photovoltaic module involves similar processes and machines that are required to fabricate conventional photovoltaic modules. Therefore, the method of fabrication of the photovoltaic module is easy, quick and cost effective.

In addition, the concentrating elements may be formed separately, and are in a pre-molded form or re-molded the pre-molded concentrating elements. Therefore, optical defects, such as void spaces and air bubbles within the photovoltaic module, are minimized, while quickening the process of fabrication, and reducing cost of assembly and fabrication.

Moreover, the photovoltaic module provides maximized outputs, at appropriate configurations of the photovoltaic strips and appropriate levels of concentration. The concentrating elements provide concentration ratios between 5:1 and 1.5:1, and concentrate solar energy onto the photovoltaic strips. Therefore, the photovoltaic module requires lesser amount of semiconductor material to generate same electrical output compared to conventional flat photovoltaic modules.

### BRIEF DESCRIPTION OF DRAWINGS

Embodiments of the present invention will hereinafter be described in conjunction with the appended drawings provided to illustrate and not to limit the present invention, wherein like designations denote like elements, and in which:

FIG. 1 is a perspective view of a base substrate for a photovoltaic module, in accordance with an embodiment of the present invention;

FIG. 2 illustrates a top view of a base substrate, in accordance with an embodiment of the present invention;

FIG. 3 illustrates a top view of a base substrate, in accordance with another embodiment of the present invention;

FIG. 4 illustrates a top view of a base substrate, in accordance with yet another embodiment of the present invention;

FIG. 5 illustrates a top view of a base substrate, in accordance with still another embodiment of the present invention;

FIG. 6 illustrates a cross sectional view of a base substrate, in accordance with an embodiment of the present invention;

FIG. 7 illustrates a cross sectional view of a base substrate, in accordance with another embodiment of the present invention;

FIG. 8 illustrates a cross sectional view of a base substrate, in accordance with yet another embodiment of the present invention;

FIG. 9a illustrates a blown-up view of a photovoltaic module, in accordance with an embodiment of the present invention;

FIG. 9b illustrates a blown-up view of a photovoltaic module, in accordance with another embodiment of the present invention;

FIG. 10a illustrates a cross-sectional view of the photovoltaic module, in accordance with an embodiment of the present invention;

FIG. 10b illustrates a cross-sectional view of the photovoltaic module, in accordance with an embodiment of the present invention;

FIG. 11 illustrates how photovoltaic strips are connected through a plurality of conductors, in accordance with an embodiment of the present invention;

FIG. 12 is a perspective view of a string configuration of photovoltaic strips, in accordance with an embodiment of the present invention;

FIG. 13 is a perspective view illustrating optical vees placed with string configuration 1200, in accordance with an embodiment of the present invention;

FIG. 14 is a perspective view illustrating a lay-up of a transparent member over the optical vees, in accordance with an embodiment of the present invention;

FIG. 15 is a perspective view of the photovoltaic module so formed, in accordance with an embodiment of the present invention;

FIG. 16 illustrates a system for manufacturing photovoltaic module, in accordance with an embodiment of the present invention;

FIG. 17 illustrates a system for manufacturing photovoltaic module, in accordance with another embodiment of the present invention;

FIG. 18 is a flow diagram illustrating a method for fabricating a photovoltaic module, in accordance with an embodiment of the present invention;

FIG. 19 is a flow diagram illustrating a method for fabricating a photovoltaic module, in accordance with another embodiment of the present invention;

FIG. 20 is a flow diagram illustrating a method for fabricating a photovoltaic module, in accordance with another embodiment of the present invention;

FIG. 21 illustrates a method for manufacturing a system for generating electricity from solar energy, in accordance with an embodiment of the present invention;

FIG. 22 illustrates a method for manufacturing a system for generating electricity from solar energy, in accordance with another embodiment of the present invention;

FIG. 23 illustrates a system for generating electricity from solar energy, in accordance with an embodiment of the present invention; and

FIG. 24 illustrates a system for generating electricity from solar energy, in accordance with another embodiment of the present invention.

### DETAILED DESCRIPTION

Embodiments of the present invention provide a method, system and apparatus for generating electricity from solar energy, and a method and system for fabricating the photovoltaic module. In the description herein for embodiments of the present invention, numerous specific details are provided, such as examples of components and/or mechanisms, to provide a thorough understanding of embodiments of the present invention. One skilled in the relevant art will recognize, however, that an embodiment of the present invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

### Glossary

Photovoltaic module: A photovoltaic module is a packaged interconnected assembly of photovoltaic strips, which converts solar energy into electricity by the photovoltaic effect.
Base substrate: A base substrate is a term used to describe the base member of photovoltaic module on which photovoltaic strips are placed. The base substrate has an electrically insulated top surface.
Stiffener: A stiffener is a member integrated with the base substrate for stiffening the base substrate. The stiffener avoids warpage or deformation of the base substrate when subjected to high temperatures.
Photovoltaic strip: A photovoltaic strip is a part of semiconductor wafer used in the fabrication of photovoltaic module.
Optical vee: An optical vee is a member with at least two surface arranged in the shape of ‘inverted-V’.
Polymeric material: A polymeric material is a substance composed of molecules with large molecular mass composed of repeating structural units, or monomers, connected by covalent chemical bonds.
Concentrating element: A concentrating element is an optical member that acts as a medium for concentrating sunlight.
Conductors: Elements for electrically connecting the concentrating elements to form a circuit.
Space: Space is the area between the adjacent photovoltaic strips.
Cavity: Cavity is three-dimensional region formed between adjacent optical vees and the photovoltaic strip that is placed between the adjacent optical vees.
Medium boundary: Medium boundary is a boundary between two mediums. For example, a medium boundary is formed at a boundary between glass and air.
Optically coupled: Optically coupled means a connection of two media of different/same refractive index so that there is no loss of light at the medium boundary.
Laminate: Laminate is an entire assembly of the photovoltaic strip, base substrate, optical vee and transparent member joined by the polymeric material.
Transparent member: Transparent member is an optically clear member placed over the photovoltaic module to seal and protect the photovoltaic module from environmental damage.
Anti-reflective coating: Anti-reflective coating is a coating over the transparent member to reduce loss of solar energy incident on the photovoltaic module.
Dicer: A dicer is for dicing a semiconductor wafer to form the photovoltaic strips.
Stringer: A stringer is for connecting the photovoltaic strips through one or more conductors.
Strip-arranger: A strip arranger is for arranging the photovoltaic strips over a base substrate.
Optical-vee placer: An optical-vee placer is for placing the optical vees in the spaces between the photovoltaic strips.
Dispenser: A dispenser is for dispensing the polymeric material in a fluid state over the cavities to form the moulded concentrating elements.
Concentrator-placer: A concentrator-placer is for placing the concentrating elements over the cavities.
Heater: A heater is for heating the photovoltaic module. For example, the photovoltaic module may be heated using the heater during lamination.
Positioning unit: A positioning unit is for positioning the transparent member over the optical vees.
Power-consuming unit: A power-consuming unit is for consuming and/or storing the power generated by the photovoltaic module.
AC Load: AC Load is a device that operates on Alternating Current (AC).
DC Load: DC Load is a device that operates on Direct Current (DC).
Charge controller: A charge controller controls the amount of charge consumed by the power-consuming unit.
Inverter: An inverter converts the electricity from a first form to a second form. For example, it converts electricity from AC to DC and vice-versa.

The photovoltaic module includes a base substrate for providing a support to the photovoltaic module. One or more stiffeners are integrated with the base substrate. The stiffeners stiffen the base substrate. Stiffeners increase the strength of the base substrate and enable the base substrate to support larger photovoltaic modules. Further, the stiffeners avoid warpage or deformation of the photovoltaic module when subjected to high temperatures during its fabrication or use. The integration of the base substrate and the stiffeners may be performed in many ways. In an example, the stiffeners may be attached over at least one surface of the base substrate. In another example, the base substrate and the stiffeners are integrated in a composite form. Examples of the stiffeners may include, but are not limited to, wires, strips, sheets, rods, granules or fibers. Further, the stiffeners may be made of various materials, but not limited to, metal, steel, stainless steel or any rigid material with high young's modulus. In accordance with an embodiment of the present invention, the stiffeners are made of a thermally-conductive material. In such a case, the stiffeners provide high thermal conductivity to the photovoltaic module and act as a heat sink. This is desirable as the efficiency of the photovoltaic module reduces at high temperatures. Examples of the thermally-conductive material include, but are not limited, boron nitride (BN), aluminium oxide (Al₂O₃), and metals, such as aluminium.

One or more photovoltaic strips are arranged over the base substrate in a predefined manner. The predefined manner may, for example, be a series and/or parallel arrangement, such that electrical output is maximized. For example, the photovoltaic strips may be rectangular in shape, and may be arranged parallel to each other with spaces in between two adjacent photovoltaic strips. The photovoltaic strips may be formed by dicing a semiconductor wafer. In another example, the photovoltaic strips may be circular or arc-like in shape, and may be arranged in the form of concentric circles. The photovoltaic strips may also be square, triangular, or any other shape, in accordance with a desired configuration. The photovoltaic strips are arranged substantially parallel to each other with spaces in between adjacent photovoltaic strips. The photovoltaic strips are electrically connected through one or more conductors in series and/or parallel.

A plurality of optical vees are placed in the spaces between the photovoltaic strips, such that a plurality of cavities are formed between adjacent optical vees. For example, the optical vees may be placed in a manner that each photovoltaic strip has two adjacent optical vees. In an embodiment of the present invention, the plurality of cavities formed between adjacent optical vees forms a trapezoidal shape in cross-section. The optical vees are for concentrating solar energy over the photovoltaic strips. The optical vees may be hollow or solid.

In first embodiment of the present invention, the optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. The optical vees may, for example, be made of any material that provides desired optical properties. Examples of such material include, but are not limited to, glass, plastics, and acrylic.

In the first embodiment of the present invention, one or more concentrating elements are introduced for concentrating solar energy over the photovoltaic strips. The concentrating elements are formed by introducing a polymeric material in a fluid state over the photovoltaic strips and the optical vees, such that the polymeric material fills the cavities between the optical vees and take the shape of the cavities in cross-section. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylics, polycarbonates, and synthetic resins.

In second embodiment of the present invention, the optical vees have a reflective layer, such that sun rays incident on the reflective layer are reflected towards the photovoltaic strips. When the reflected sun rays fall on the photovoltaic strips, electricity is generated by the photoelectric effect.

In an embodiment of the present invention, the photovoltaic module includes a transparent member positioned over the optical vees. The transparent member is coated with an anti-reflective coating to reduce loss of solar energy incident on the photovoltaic module, in accordance with an embodiment of the present invention.

The acceptance angle of the photovoltaic module is chosen, such that rays within the angular limit of normal to the module may be total internally reflected or reflected towards the photovoltaic strips with minimal optical losses. Tracking mechanisms may be used to change the position of the photovoltaic module, in order to keep the rays normally incident upon the photovoltaic module while the sun moves across the sky. This further enhances the power output of the photovoltaic module.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

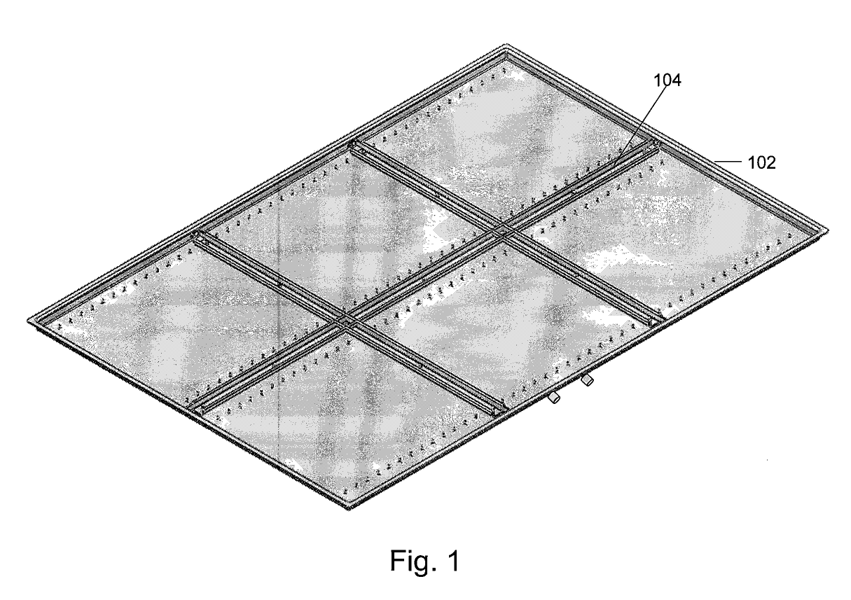

FIG. 1 is a perspective view of a base substrate 102 for a photovoltaic module, in accordance with an embodiment of the present invention. Base substrate 102 includes one or more stiffeners 104, such as stiffeners 104a, stiffeners 104b and stiffeners 104c. Stiffeners 104 are integrated with base substrate 102 for stiffening base substrate 102. Stiffeners 104 avoid warpage or deformation of base substrate 102 when subjected to high temperatures. For example, the photovoltaic module may be subjected to high temperatures during lamination. In an example, stiffeners 104 are integrated with base substrate 102 during fabrication of the photovoltaic module. This helps in reducing warpage during the fabrication of the photovoltaic module or the use of the photovoltaic module under the sun rays. The base substrate 102 and stiffeners 104 may be integrated in many ways. In an embodiment of the present invention, stiffeners 104 are attached with at least one outer surface of base substrate 102. For example, stiffeners 104 are attached in the form of sheet with base substrate 102. In another embodiment of the present invention, base substrate 102 and stiffeners 104 are integrated in a composite form. For example, stiffeners 104 are sandwiched between two layers of base substrate 102. Stiffeners 104 may, for example, be wires, strips, sheets, rods, granules or fibers. In this embodiment of the present invention, stiffeners 104 are attached over a surface of base substrate parallelly and perpendicularly. Stiffeners 104 may be made of light weight materials, but not limited to, metal, metal alloys, hard plastic, steel, stainless steel or any rigid material with high young's modulus. Stiffeners enable fabrication of large-sized photovoltaic modules without any significant increase in the weight of the photovoltaic module.

In accordance with an embodiment of the present invention, stiffeners 104 are made of a thermally-conductive material. In such a case, stiffeners 104 provide high thermal conductivity to the photovoltaic module and act as a heat sink. This is desirable as the efficiency of the photovoltaic module reduces at high temperatures. Examples of the thermally-conductive material include, but are not limited, boron nitride (BN), aluminium oxide (Al₂O₃), and metals, such as aluminium.

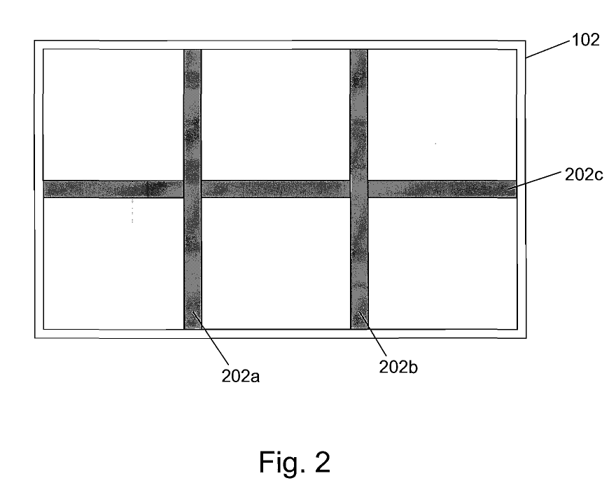

FIG. 2 illustrates a top view of base substrate 102, in accordance with an embodiment of the present invention. Base substrate 102 includes stiffeners 202, such as a stiffener 202a, a stiffener 202b and a stiffener 202c. In this embodiment of the present invention, stiffeners 202, in form of strips, are attached over a surface of base substrate 102. Stiffener 202a and stiffener 202b are attached over base substrate 102 and are arranged parallel to each other. Further, stiffener 202c is attached over base substrate perpendicular to stiffener 202a and stiffener 202b. In accordance with an embodiment of the present invention, stiffeners 202 are made of a thermally-conductive material.

It is to be understood that the specific designation of stiffeners 202 is for the convenience of the reader and is not to be construed as limiting. Further, the number of stiffeners 202 integrated with base substrate 102 may be varied based on the stiffness required.

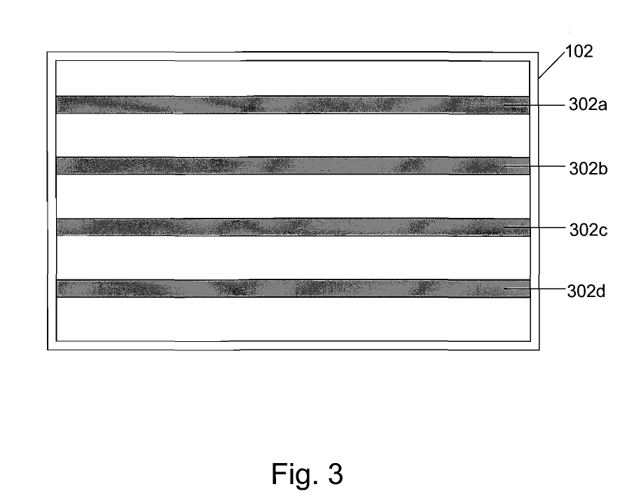

FIG. 3 illustrates a top view of base substrate 102, in accordance with another embodiment of the present invention. Base substrate 102 includes a stiffeners 302, such as a stiffener 302a, a stiffener 302b, a stiffener 302c and a stiffener 302d. In this embodiment of the present invention, stiffeners 302 are attached over a surface of base substrate 102. In an embodiment, stiffeners 302 may be formed in the form of cylindrical rods, flat rectangles or thin wire. In accordance with an embodiment of the present invention, stiffeners 302 are made of a thermally-conductive material.

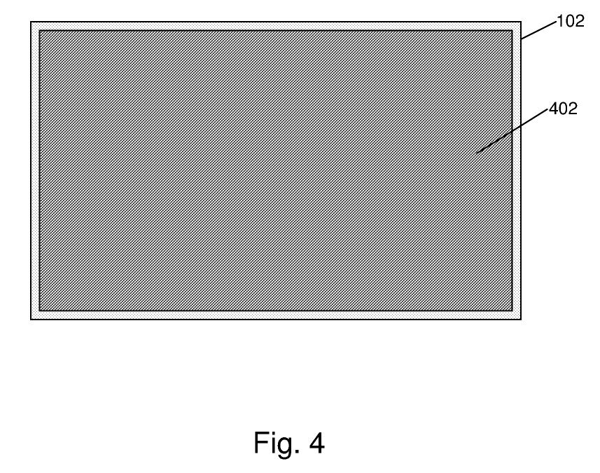

FIG. 4 illustrates a top view of base substrate 102, in accordance with yet another embodiment of the present invention. Base substrate 102 includes a stiffener 402. Stiffener 402 is attached over a surface of base substrate 102. Stiffener 402 is in form of sheet. In an embodiment of the present invention, various such sheets could be attached with base substrate 102. In accordance with an embodiment of the present invention, stiffener 402 is made of a thermally-conductive material.

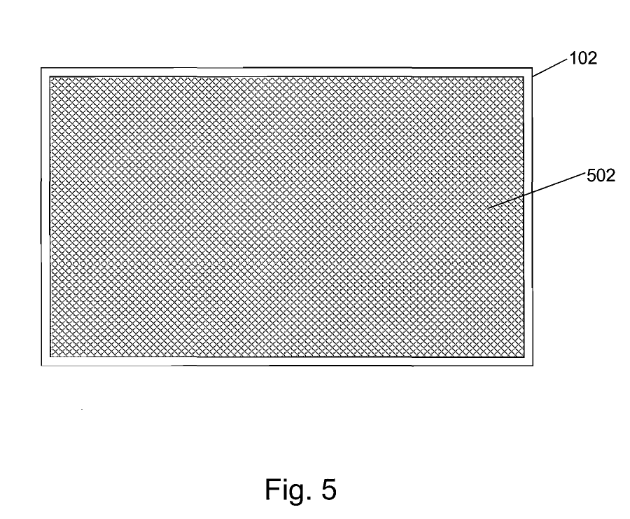

FIG. 5 illustrates a top view of base substrate 102, in accordance with still another embodiment of the present invention. Base substrate 102 includes a stiffener 502. Stiffener 502 is attached over a surface of base substrate 102. In an embodiment of the present invention, a plurality of wires at various angles may be attached to the surface of the base substrate 102 in the form a mesh. The wires may be attached perpendicular to each other. In another embodiment of the present invention, a preformed wired mesh may be attached with the base substrate 102. In accordance with an embodiment of the present invention, stiffener 502 is made of a thermally-conductive material.

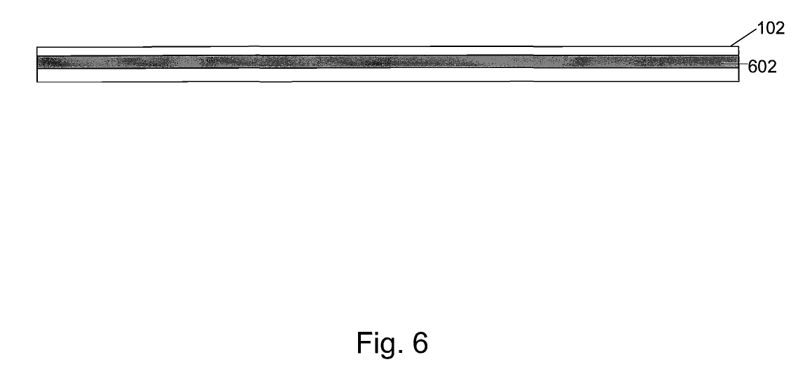

FIG. 6 illustrates a cross sectional view of base substrate 102, in accordance with an embodiment of the present invention. Base substrate 102 includes a stiffener 602. Base substrate 102 and stiffener 602 are integrated in a composite form. For example, stiffener 602 is integrated between different layers of base substrate 102, such as base substrate 102a and base substrate 102b, in the form of sheet. Stiffener 602 is sandwiched between the layers of the base substrate 102. In an embodiment of the present invention, stiffener 602 may be integrated with the base substrate 102 in molten form and thereafter cured to form a stiffened base substrate. In another embodiment of the present invention, stiffener 602 may be present in the form of a mesh.

In various embodiments of the preset invention, various such layers of stiffeners 602 could be formed inside the base substrate 102. In accordance with an embodiment of the present invention, stiffeners 602 are made of a thermally-conductive material.

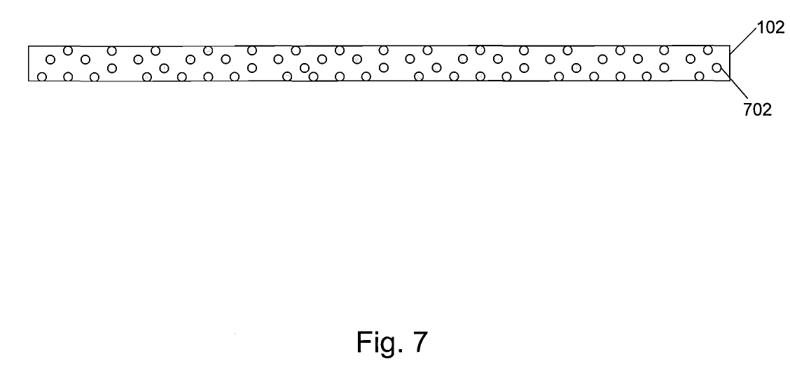

FIG. 7 illustrates a cross sectional view of base substrate 102, in accordance with another embodiment of the present invention. Base substrate 102 includes one or more stiffeners 702. Stiffeners 702 are integrated with the base substrate 102 and in a composite form. Stiffeners 702 are present inside the base substrate 102 in the form of granules. In an embodiment of the present invention, stiffeners 702 are uniformly dispersed in base substrate 102. In accordance with an embodiment of the present invention, stiffeners 702 are made of a thermally-conductive material.

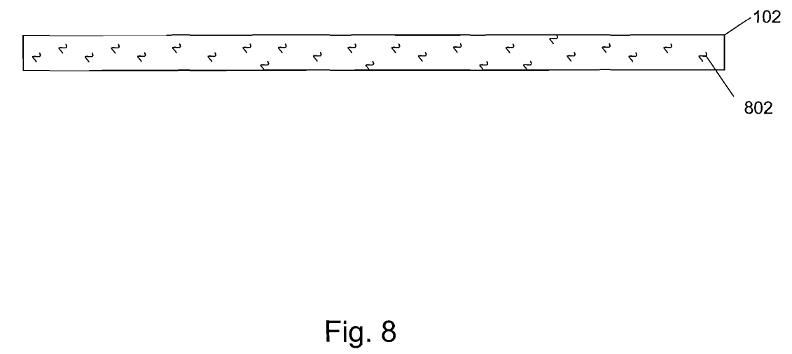

FIG. 8 illustrates a cross sectional view of base substrate 102, in accordance with yet another embodiment of the present invention. Base substrate 102 includes one or more stiffeners 802. Stiffeners 802 are integrated in the base substrate 102 in a composite form. In this embodiment the stiffeners 802 are present in the form of fibers. In an embodiment of the present invention, stiffeners 802 are uniformly dispersed in base substrate 102. In accordance with an embodiment of the present invention, stiffeners 802 are made of a thermally-conductive material.

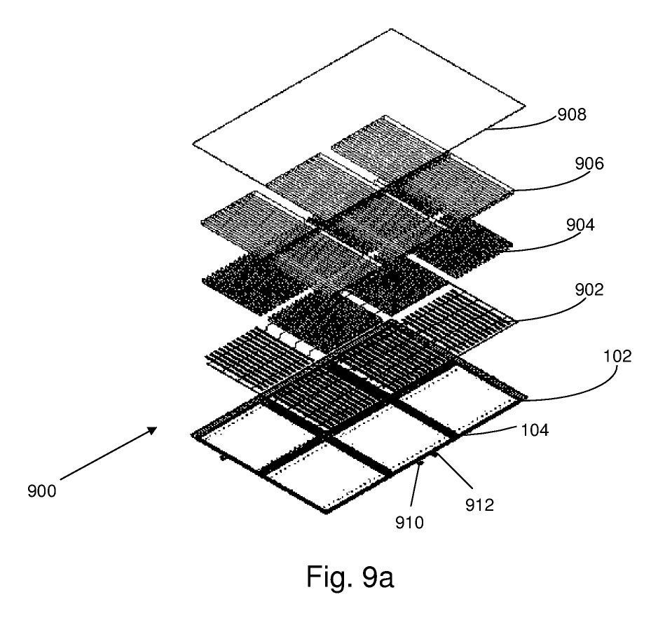

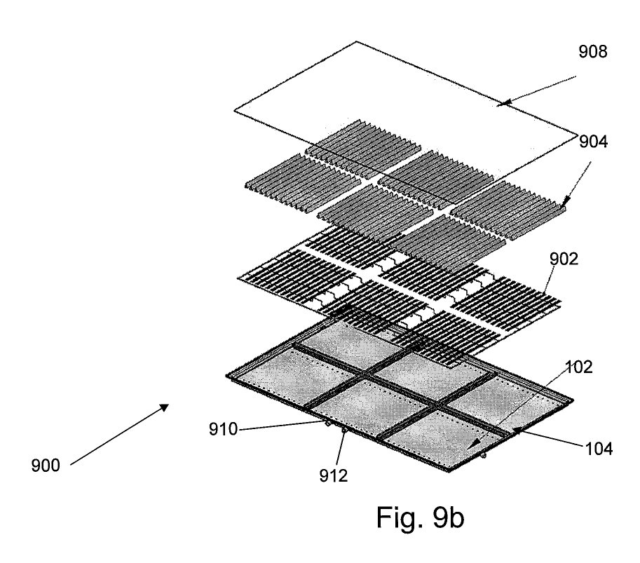

FIG. 9a illustrates a blown-up view of a photovoltaic module 900a, in accordance with an embodiment of the present invention. Photovoltaic module 900a includes base substrate 102, stiffeners 104, one or more photovoltaic strips 902, a plurality of optical vees 904, a plurality of concentrating elements 906, a transparent member 908, a positive terminal 910 and a negative terminal 912.

Base substrate 102 provides support to photovoltaic module 900a. With reference to FIG. 9a, base substrate 902 is rectangular in shape.

Stiffeners 104 are integrated with base substrate 102 for stiffening base substrate 102 to avoid the warpage. In an embodiment of the present invention, stiffeners 104 are attached over at least one outer surface of the base substrate. In another embodiment of the present invention, base substrate 102 and stiffeners 104 are integrated in a composite form. Stiffeners 104 may, for example, be wires, strips, sheets, rods, granules or fibers.

Photovoltaic strips 902 are arranged over base substrate 102. With reference to FIG. 9a, photovoltaic strips 902 are rectangular in shape and are arranged parallel to each other with spaces in between two adjacent photovoltaic strips. Photovoltaic strips 902 are made of a semiconductor material. Examples of semiconductors include, but are not limited to, monocrystalline silicon (c-Si), polycrystalline or multicrystalline silicon (poly-Si or mc-Si), ribbon silicon, cadmium telluride (CdTe), copper-indium diselenide (CuInSe₂), combinations of III-V, II-VI elements in the periodic table that have photovoltaic effect, copper indium/gallium diselenide (CIGS), gallium arsenide (GaAs), germanium (Ge), gallium indium phosphide (GaInP₂), organic semiconductors such as polymers and small-molecule compounds like polyphenylene vinylene, copper phthalocyanine and carbon fullerenes, amorphous silicon (a-Si or a-Si:H), protocrystalline silicon, and nanocrystalline silicon (nc-Si or nc-Si:H). When electromagnetic radiation falls over photovoltaic strips 902, electron-hole pairs are separated by some means before they recombine giving rise to a voltage. When a load is connected across the two electrodes, the generated voltage rise a current producing electrical energy.

With reference to FIG. 9a, optical vees 904 are placed in the spaces between photovoltaic strips 902 and at the outermost sides, such that a plurality of trapezoidal cavities are formed between optical vees 904. Concentrating elements 906 are formed by filling the trapezoidal cavities. In an embodiment of the present invention, concentrating elements 906 are formed by pouring a polymeric material in a fluid state over the trapezoidal cavities such that concentrating elements 906 takes the shape of the trapezoidal cavities.

In another embodiment of the present invention, concentrating elements are formed by placing a pre-molded concentrating elements over the trapezoidal cavities. In yet another embodiment of the present invention, concentrating elements 906 are formed by re-molding the pre-molded concentrating elements over the trapezoidal cavities. In an embodiment, space or air bubble left between concentrating elements 906 and photovoltaic strips 902, and between concentrating elements 906 and optical vees 904 is minimized. Concentrating elements 906 are optically coupled to photovoltaic strips 902. Concentrating elements 906 concentrate the electromagnetic radiation over photovoltaic strips 902. In an embodiment of the present invention, concentrating elements 906 act as a laminate for encapsulating photovoltaic module 900a. The level of concentration of the electromagnetic radiation may be varied depending on the shape, size and refractive index of concentrating elements 906.

Transparent member 908 is optically coupled to concentrating elements 906, in accordance with an embodiment of the present invention. Transparent member 908 seals with base substrate 102 and protects concentrating elements 906 and photovoltaic strips 902 from environmental damage, while allowing electromagnetic radiation falling on its surface to pass to concentrating elements 906. The refractive index of transparent member 908 can be varied, and the reflectivity of transparent member 908 can be minimized, to increase the efficiency of concentration. For example, transparent member 908 may be coated with an anti-reflective coating, so that no reflection occurs at a medium boundary between air and transparent member 908. In addition, no refraction occurs at a medium boundary between transparent member 908 and concentrating elements 906 when the refractive index of transparent member 908 is equal to the refractive index of concentrating elements 906. Rays, incident on the medium boundary between transparent member 908 and concentrating elements 906, refract with an angle of refraction smaller than an angle of incidence when the refractive index of transparent member 908 is less than the refractive index of concentrating elements 906. The shape of transparent member may, for example, be flat or curved.

Positive terminal 910 and negative terminal 912 enable the photovoltaic module to connect with the external devices, such that they may draw the electricity generated from the photovoltaic module. Positive terminal 910 may be several in numbers and may be located at any position on base substrate 102. Similarly, negative terminal 912 may be several in numbers and may be located at any position on the base substrate 102.

In accordance with an embodiment of the present invention, stiffeners 104 are attached with base substrate 102 on the same surface to where optical vees 904 are placed. In accordance with another embodiment of the present invention, stiffeners 104 are attached with base substrate 102 on the opposite surface to where optical vees 904 are placed. With reference to FIG. 9a, stiffeners 104 are attached with base substrate 102 on the same surface to where optical vees 904 are placed.

FIG. 9b illustrates a blown-up view of a photovoltaic module 900b, in accordance with another embodiment of the present invention. Photovoltaic module 900b includes base substrate 102, one or more stiffeners 104, one or more photovoltaic strips 902, a plurality of optical vees 904, a transparent member 908, a positive terminal 910 and a negative terminal 912

Base substrate 102 provides support to photovoltaic module 900b. With reference to FIG. 9b, base substrate 102 is rectangular in shape. Base substrate 102 can be made of any material that is tolerant to moisture, Ultra Violet (UV) radiation, abrasion, and natural temperature variations. Examples of such materials include, but not limited to, aluminium, steel, plastics and suitable polycarbonates. In addition, base substrate 102 may, for example, be made of plastics with metal coating or plastics with high thermal conductivity fillers. Examples of such fillers include, but are not limited to, boron nitride (BN), aluminium oxide, (Al₂O₃), and metals. Base substrate 102 has an electrically insulated top surface. For example, base substrate 102 may be coated with a layer of electrically insulating material such as anodized aluminium. Stiffener 104 is integrated with base substrate 102 for stiffening base substrate 102 to avoid the warpage. With reference to FIG. 9b, stiffeners 104 are attached over at least one outer surface of the base substrate. Stiffeners 104 may, for example, be wires, strips, sheets, rods, granules or fibers. Photovoltaic strips 902 are arranged over base substrate 102. With reference to FIG. 9b, photovoltaic strips 902 are rectangular in shape and are arranged parallel to each other with spaces in between two adjacent photovoltaic strips.

With reference to FIG. 9b, optical vees 904 are placed in the spaces between photovoltaic strips 902. Optical vees 904 concentrate the electromagnetic radiation over photovoltaic strips 902. The level of concentration may be varied depending on the shape and size of optical vees 904. Optical vees 904 are inverted-V-shaped in cross-section, in accordance with an embodiment of the present invention. In accordance with another embodiment of the present invention, optical vees 904 are compound-parabolic-shaped in cross-section. Optical vees 904 have a reflective layer, such that sun rays incident on the reflective layer are reflected towards photovoltaic strips 902. When the reflected sun rays fall on photovoltaic strips 902, electricity is generated by the photoelectric effect. Optical vees 904 may, for example, be made of glass, plastics, polymeric materials, Ethyl Vinyl Acetate (EVA), Thermoplastic Poly-Urethane (TPU), Poly Vinyl Butyral (PVB), silicone, acrylics, polycarbonates, metals, metallic alloys, metal compounds, and ceramics. In accordance with an embodiment of the present invention, optical vees 904 comprise a reflection-enhancing layer to enhance the reflectivity of optical vees 904.

In an embodiment of the present invention, optical vees 904 are formed by polishing surfaces of a prism of a reflective material. In this case, optical vees 904 are solid. In another embodiment of the present invention, optical vees 904 are formed by polishing a sheet of a reflective material, which may be bent in a desired shape of optical vees 904. In such a case, optical vees 904 are hollow and optical vees 904 may, for example, be V-shaped or triangular in cross-section. In yet another embodiment of the present invention, optical vees 904 are made of a foil of a reflective material sandwiched between two moldable sheets. The sandwiched foil is bent in a desired shape of optical vees 904. As the moldable sheets are electrically non-conductive, the optical vees 904 can be placed over the conductors. In such a case, optical vees 904 are hollow and optical vees 904 may, for example, be V-shaped or triangular in cross-section. In still another embodiment of the present invention, the reflective layer is formed by coating optical vees 904 with a reflective material.

Transparent member 908 is positioned over optical vees 904. Transparent member 908 seals with base substrate 102 and protects optical vees 904 and photovoltaic strips 902 from environmental damage, while allowing electromagnetic radiation falling on its surface to pass through. With reference to FIG. 9b, transparent member 908 is flat rectangular in shape. In other cases, transparent member 908 may have any desired shape, such as a curved shape. The refractive index of transparent member 908 can be varied, while minimizing the reflectivity of transparent member 908, to increase the efficiency of concentration. Transparent member 908 is coated with an anti-reflective coating on its top and bottom surfaces, so that no reflection occurs at medium boundaries between air and transparent member 908.

Positive terminal 910 and negative terminal 912 enable the photovoltaic module to connect with the external devices, such that they may draw the electricity generated from the photovoltaic module. Positive terminal 910 may be several in numbers and may be located at any position on base substrate 102. Similarly, negative terminal 912 may be several in numbers and may be located at any position on the base substrate 102.

In an embodiment of the present invention, the fabrication of photovoltaic module 900b is done by using a high speed robotic assembly. The robotic assembly includes one or more robotic arms, which are employed for performing various processes during the fabrication. In one example, a robotic arm may be used to connect photovoltaic strips 902 over base substrate 102. In another example, the placement of optical vees 904 in between photovoltaic strips 902 may be done with another robotic arm. The processes of wire bonding and die attachment in fabrication of photovoltaic module 900b may also be performed with the robotic arms.

It is to be understood that the specific designation for photovoltaic modules 900a and 900b and their components is for the convenience of the reader and is not to be construed as limiting photovoltaic modules 900a and 900b and their components to a specific number, size, shape, type, material, or arrangement.

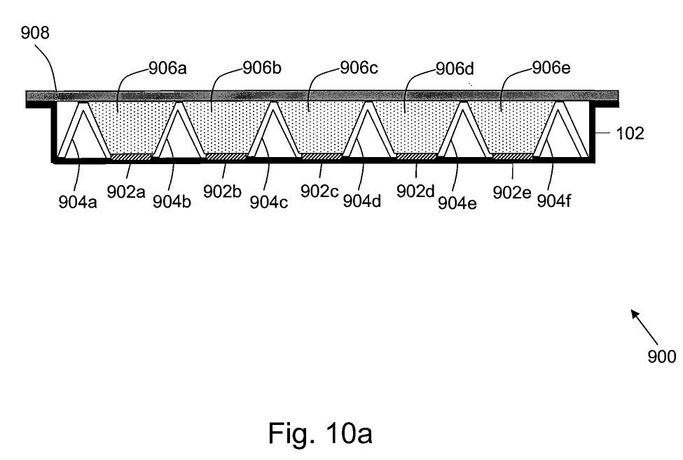

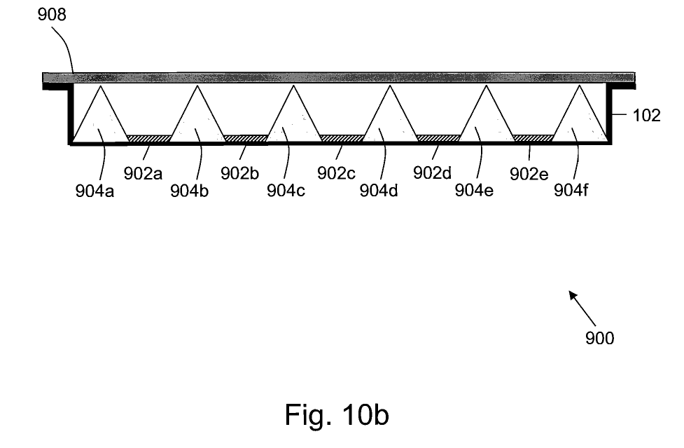

FIG. 10a illustrates a cross-sectional view of photovoltaic module 900a, in accordance with an embodiment of the present invention. In FIG. 10a, photovoltaic strips 902 are shown as a photovoltaic strip 902a, a photovoltaic strip 902b, a photovoltaic strip 902c, a photovoltaic strip 902d, and a photovoltaic strip 902e. Optical vees 904 are shown as an optical vee 904a, an optical vee 904b, an optical vee 904c, an optical vee 904d, an optical vee 904e, and an optical vee 904f. Concentrating elements 906 are shown as a moulded concentrating element 906a, a concentrating element 906b, a concentrating element 906c, a concentrating element 906d, and a concentrating element 906e. With reference to FIG. 10a, concentrating element 906a is filled in a cavity between optical vee 904a and optical vee 904b, concentrating element 906b is filled in a cavity between optical vee 904b and optical vee 904c, and so on. As mentioned above, space or air bubble left between concentrating elements 906 and photovoltaic strips 902, and between concentrating elements 906 and optical vees 904 is minimized.

In accordance with an embodiment of the present invention, a single photovoltaic strip, a single optical vee and a single moulded concentrating element are collectively termed as a ‘low concentrator unit’. A plurality of such low concentrator units may be combined together to form a photovoltaic module.

FIG. 10b illustrates a cross-sectional view of photovoltaic module 900b, in accordance with another embodiment of the present invention. In FIG. 10b, photovoltaic strips 902 are shown as a photovoltaic strip 902a, a photovoltaic strip 902b, a photovoltaic strip 902c, a photovoltaic strip 902d, and a photovoltaic strip 902e. Optical vees 904 are shown as an optical vee 904a, an optical vee 904b, an optical vee 904c, an optical vee 904d, an optical vee 904e, and an optical vee 904f. With reference to FIG. 10b, optical vee 904a and optical vee 904b concentrate solar energy towards photovoltaic strip 902a, optical vee 904b and optical vee 904c concentrate solar energy towards photovoltaic strip 902b, and so on. With reference to FIG. 10b, optical vees 904 are solid. Transparent member 908 is coated with an anti-reflective coating and is placed over base substrate 102 enclosing photovoltaic strip 902a, photovoltaic strip 902b, photovoltaic strip 902c, photovoltaic strip 902d, photovoltaic strip 902e, optical vee 904a, optical vee 904b, optical vee 904c, optical vee 904d, optical vee 904e, and optical vee 904f. It should be noted that the enclosure of base substrate 102 is not limited to the number of elements shown in the figure.

In accordance with another embodiment of the present invention, a single photovoltaic strip and a single optical vee are collectively termed as a ‘low concentrator unit’. A plurality of such low concentrator units may be combined together to form a photovoltaic module.

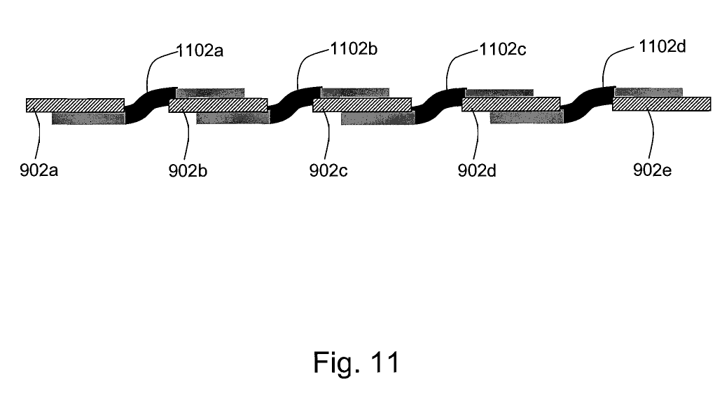

FIG. 11 illustrates how photovoltaic strips 304 are connected through a plurality of conductors, in accordance with an embodiment of the present invention. With reference to FIG. 11, photovoltaic strips 902 are connected in series. In such a configuration, the p-side of photovoltaic strip 902a is connected to the n-side of photovoltaic strip 902b using a conductor 1102a, the p-side of photovoltaic strip 902b is connected to the n-side of photovoltaic strip 902c using a conductor 1102b, the p-side of photovoltaic strip 902c is connected to the n-side of photovoltaic strip 902d using a conductor 1102c, and the p-side of photovoltaic strip 902d is connected to the n-side of photovoltaic strip 902e using a conductor 1102d.

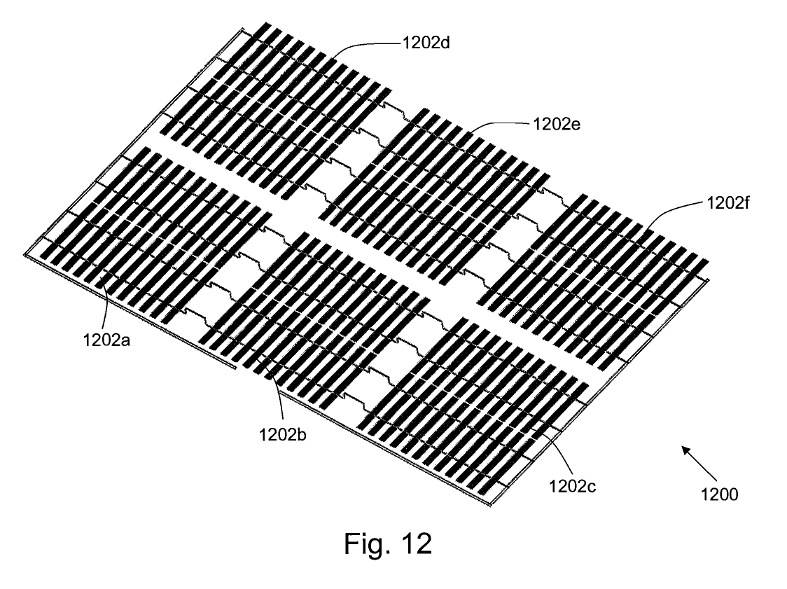

FIG. 12 is a perspective view of a string configuration 1200 of photovoltaic strips, in accordance with an embodiment of the present invention. A string 1202a, a string 1202b, a string 1202c, a string 1202d, a string 1202e and a string 1202f are formed by stringing a plurality of photovoltaic strips in series. String 1202a, string 1202b and string 1202c are combined in series. Similarly, string 1202d, string 1202e and string 1202f are combined in series. These two series configurations are then combined in parallel. String configuration 1200 is arranged over base substrate 102, in accordance with an embodiment of the present invention.

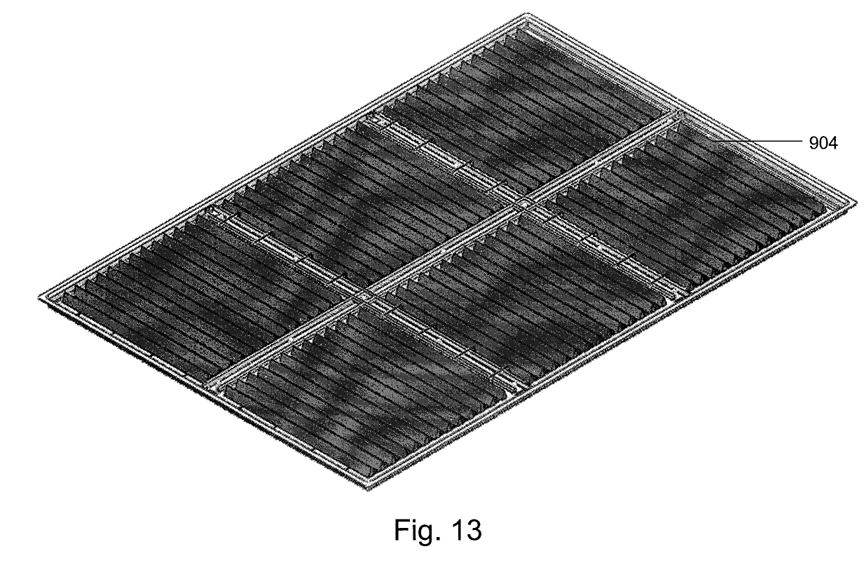

FIG. 13 is a perspective view illustrating optical vees 904 placed with string configuration 1200, in accordance with an embodiment of the present invention. Optical vees 904 with a reflective layer are placed parallel to string configuration 1200 over base substrate 102, in an embodiment of the present invention. In another embodiment of the present invention, a plurality of pre-molded EVA elements (not shown in the figure) are placed over string configuration 1200 and optical vees 904. The moulded EVA elements are optically coupled to the photovoltaic strips in string configuration 1200. The moulded EVA elements form a trapezoidal shape in cross-section, complementary to optical vees 904.

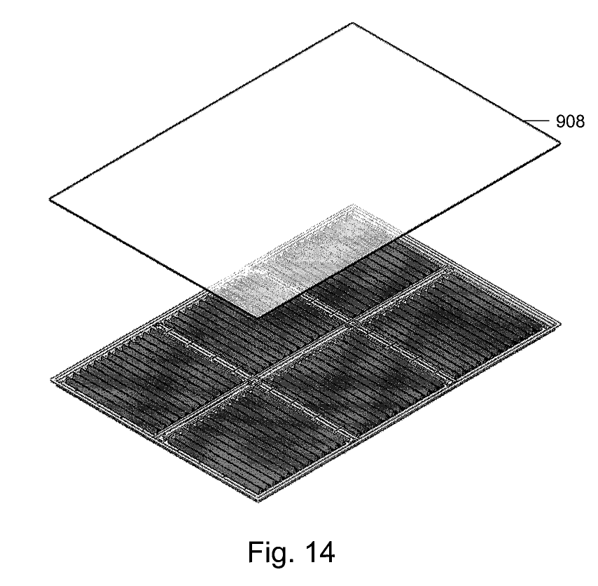

FIG. 14 is a perspective view illustrating a lay-up of a transparent member 908 over the optical vees, in accordance with an embodiment of the present invention. The shape of the transparent member may, for example, be flat or curved.

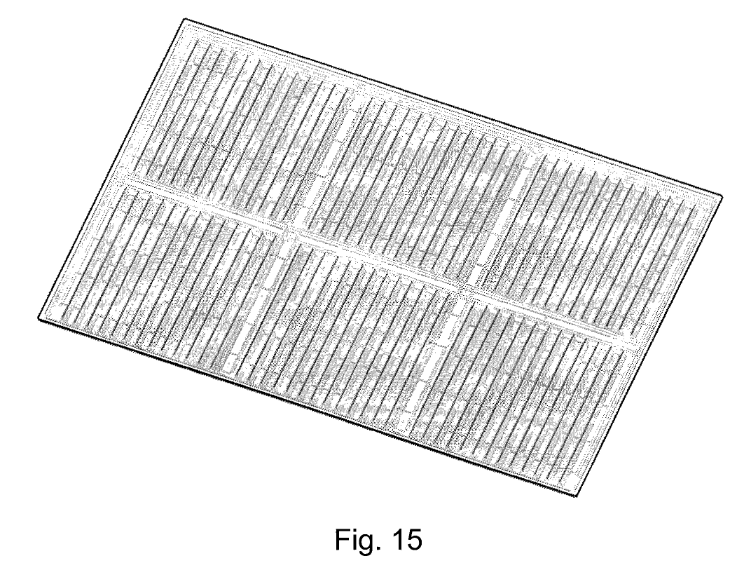

FIG. 15 is a perspective view of the photovoltaic module so formed, in accordance with an embodiment of the present invention. It is to be understood that the specific designation for the photovoltaic module and its components as shown in FIGS. 12-15 is for the convenience of the reader and is not to be construed as limiting the photovoltaic module and its components to a specific number, size, shape, type, material, or arrangement.

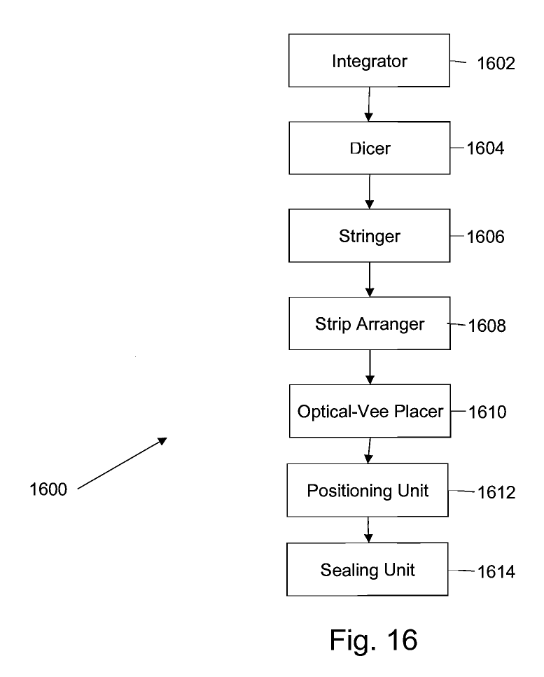

FIG. 16 illustrates a system 1600 for manufacturing photovoltaic module 900b, in accordance with an embodiment of the present invention. System 1600 includes an integrator 1602, a dicer 1604, a stringer 1606, a strip arranger 1608, an optical-vee placer 1610, a positioning unit 1612 and a sealing unit 1614.

Integrator 1602 integrates one or more stiffeners with a base substrate, the stiffeners stiffen the base substrate. Integrator 1602 may, for example, be a robotic assembly. In an embodiment of the present invention, integrator 1602 attaches the stiffeners with at least one outer surface of the base substrate. For example, integrator 1602 may attach the stiffeners with the help of screws done by a robotic assembly. In another embodiment of the present invention, integrator 1602 integrates the stiffeners and the base substrate in a composite form. For example, integrator 1602 may integrate the stiffeners into the base substrate by an automated composite-forming machine.

In an embodiment of the present invention, dicer 1604 dices a semiconductor wafer to form a plurality of photovoltaic strips. Dicer 1604 may, for example, be a mechanical saw or a laser dicer. Laser dicers dice a semiconductor wafer from its base-side using a laser source. This provides a clean cut without any burrs, and involves minimal device damage.

Stringer 1606 connects the photovoltaic strips through one or more conductors in a predefined manner, such that one or more strings of photovoltaic strips are formed. The photovoltaic strips are connected such that spaces are formed in between adjacent photovoltaic strips. Stringer 1606 may, for example, perform soldering using a manual process, a semi-automatic process, or a high-speed soldering machine. Solder-coated copper strips may, for example, be used as the conductors. Alternatively, stringer 1606 may perform wire bonding using a high-speed robotic assembly.

Strip arranger 1608 arranges the strings of photovoltaic strips over a base substrate. Strip arranger 1608 may, for example, be a pick-and-place unit that picks the strings of photovoltaic strips, and aligns and places them as per a specified arrangement.

In accordance with another embodiment of the present invention, strip arranger 1608 arranges individual photovoltaic strips over a base substrate, and stringer 1606 connects the photovoltaic strips with each other over the base substrate. In such a case, strip arranger 1608 may, for example, be a pick-and-place unit that picks photovoltaic strips, and aligns and places them as per a specified arrangement.

Optical-vee placer 1610 places a plurality of optical vees in spaces between the photovoltaic strips. Optical-vee placer 1610 may, for example, be a pick-and-place unit that picks optical vees, and aligns and places them as per the specified arrangement. The optical vees may be fabricated in different ways. For example, solid blocks of a reflective material may be machined to form the optical vees or surfaces of each solid block may be polished to form a reflective layer.

In an embodiment of the present invention, positioning unit 1612 positions a transparent member over the optical vees. Positioning unit 1612 may, for example, be a pick-and-place unit that picks the transparent member, and aligns and places it as per the specified arrangement. Thereafter, sealing unit 1614 seals the transparent member with the base substrate. In accordance with an embodiment of the present invention, the sealing is performed at the periphery. This may be accomplished by a resistive heating process using sealing rollers that melts a solder preform and forms a hermetic seal. Alternatively, the seal may be formed by a needle-dispensed epoxy, gasket sealing, glass frit, or EVA. In such a case, the seal so formed is non-hermetic, and an additional step of framing the photovoltaic module may be performed. This can be accomplished by mechanically attaching a frame to the photovoltaic module. The frame may be made of a metal or a metallic alloy. Aluminum may be used for this purpose, as it is cheaper and lighter than other metals and metallic alloys.

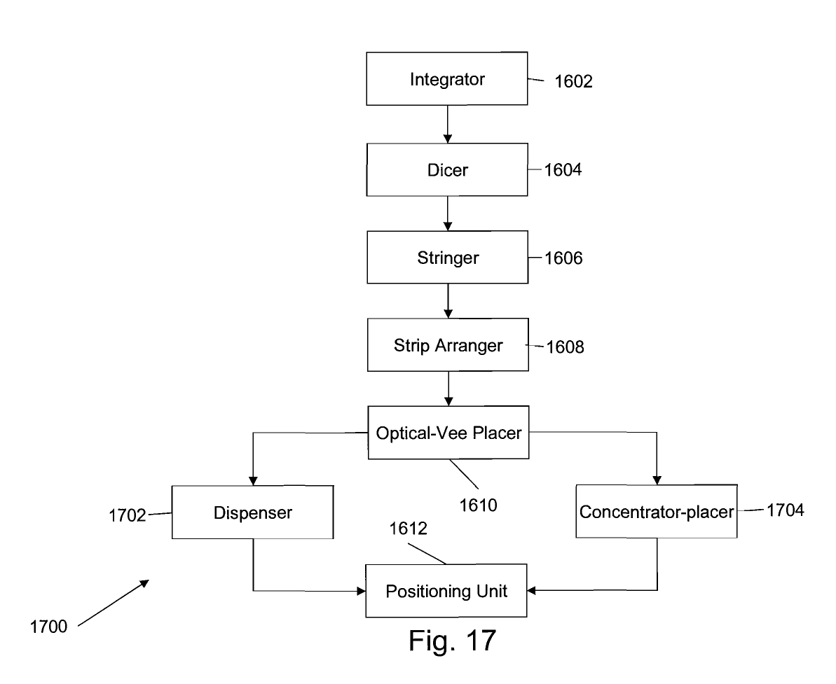

FIG. 17 illustrates a system 1700 for manufacturing photovoltaic module 900a, in accordance with another embodiment of the present invention. System 1700 includes a integrator 1602, a dicer 1604, a stringer 1606, a strip arranger 1608, an optical-vee placer 1610, a positioning unit 1612, a dispenser 1702 and a concentrator-placer 1704.

As mentioned above, Integrator 1602 integrates one or more stiffeners with a base substrate, the stiffeners stiffen the base substrate. Integrator 1602 may, for example, be a robotic assembly. Dicer 1604 dices a semiconductor wafer to form a plurality of photovoltaic strips. Stringer 1606 connects the photovoltaic strips through one or more conductors in a predefined manner, such that one or more strings of photovoltaic strips are formed. The photovoltaic strips are connected such that spaces are formed in between adjacent photovoltaic strips. Strip arranger 1608 arranges the strings of photovoltaic strips over a base substrate. Optical-vee placer 1610 places a plurality of optical vees in spaces between the photovoltaic strips such that cavities are formed between the optical vees. Optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum.

In accordance with an embodiment of the present invention, dispenser 1702 dispenses a polymeric material in a fluid state over said cavities to form one or more concentrating elements, such that the concentrating elements take the shape of said cavities. In an embodiment of the present invention, the cavities form a trapezoidal shape in cross-section. The polymeric material can be any material that is tolerant to moisture, UV radiation, abrasion, and natural temperature variations. The refractive index of the polymeric material may, for example, be 1.5 or above. Examples of the polymeric material include, but are not limited to, EVA, silicone, TPU, PVB, acrylics, polycarbonates, and synthetic resins. Dispensing unit 1702 mixes the polymeric material with a hardener before pouring the polymeric material, in accordance with an embodiment of the present invention.

In accordance with another embodiment of the present invention, concentrator-placer 1704 places one or more pre-moulded concentrating elements over said cavities. In accordance with yet another embodiment of the present invention, system 1700 also includes a heating unit for re-moulding the pre-moulded concentrating elements to form re-moulded concentrating elements. As mentioned above, positioning unit 1612 positions a transparent member over the optical vees.

Various embodiments of the present invention provide an apparatus for generating electricity from solar energy. The apparatus includes supporting means for providing support to the apparatus, stiffening means for stiffening the supporting means, the stiffening means is integrated with the supporting means, converting means for converting solar energy into electrical energy, means for connecting the converting means in a predefined manner, concentrating means for concentrating solar energy over the converting means, and transparent means for sealing the supporting means, the converting means and the concentrating means. The converting means are arranged over the supporting means with spaces in between adjacent converting means. The concentrating means are placed in the spaces between the converting means such that cavities are formed between adjacent concentrating means.

In an embodiment of the present invention, the concentrating means includes a plurality of optical vees, the optical vees comprising a first medium; and a second medium underlying said first medium, wherein the ratio of the refractive index of the first medium and the refractive index of the second medium is greater than one; and one or more concentrating elements. In an example, the concentrating elements are formed by pouring a polymeric material in a fluid state over said cavities, such that said concentrating means take the shape of said cavities. In another example, the concentrating elements are in pre-molded form. In another embodiment of the present invention, the concentrating means are in pre-molded form. In yet another embodiment of the present invention, the concentrating means include optical vees having a reflective layer, such that rays incident on the reflective layer are reflected towards the converting means. The concentrating means may be either hollow or solid.

The transparent means is positioned over the concentrating means. The supporting means, the converting means, the concentrating means and the transparent means form the apparatus in an integrated manner. The transparent means is sealed with the supporting means. The transparent means is coated with an anti-reflective coating to reduce loss of solar energy incident on the apparatus, in accordance with an embodiment of the present invention.

Examples of the supporting means include, but are not limited to, base substrate 102. Examples of the converting means include, but are not limited to, photovoltaic strips 104, and string configuration 1200. Examples of the means for connecting include, but are not limited to, conductors 1102a-d. In an embodiment of the present invention, examples of the concentrating means include, but are not limited to, optical vees 904. In another embodiment of the present invention, examples of the concentrating means include, but are not limited to, optical vees 906 and concentrating elements 906. Examples of the transparent means include, but are not limited to, transparent member 908.

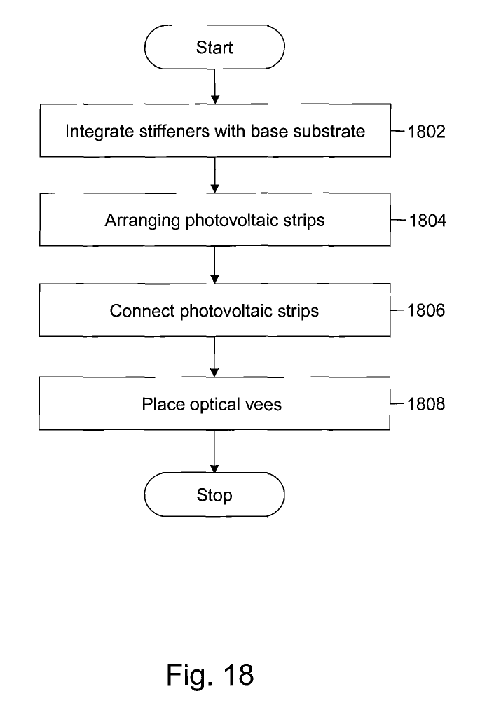

FIG. 18 is a flow diagram illustrating a method for fabricating a photovoltaic module, in accordance with an embodiment of the present invention. At step 1802, one or more stiffeners are integrated with base substrate. As mentioned earlier, the stiffeners are attached with at least one outer surface on base substrate, in an embodiment of the present invention. In another embodiment of the present invention, the base substrate and the stiffeners are integrated in a composite form. At step 1804, one or more photovoltaic strips are arranged over a base substrate in a predefined manner. As mentioned earlier, for example, the photovoltaic strips may be rectangular in shape, and may be arranged parallel to each other with spaces in between two adjacent photovoltaic strips. Alternatively, the photovoltaic strips may be circular or arc-like in shape, and may be arranged in the form of concentric circles. The photovoltaic strips may also be square, triangular, or any other shape, in accordance with a desired configuration. At step 1806, the photovoltaic strips are connected through one or more conductors. The photovoltaic strips may be connected in series and/or parallel.

At step 1808, a plurality of optical vees are placed in the spaces between the photovoltaic strips, such that one or more cavities are formed between adjacent optical vees. For example, the optical vees may be placed in a manner that each photovoltaic strip has two adjacent optical vees. The optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. Depending on the shape and configuration of the photovoltaic strips, optical vees with a suitable shape may be used. Continuing from previous examples, rectangular optical vees may be used for rectangular photovoltaic strips, while circular optical vees may be used for circular photovoltaic strips. In accordance with an embodiment of the present invention, the optical vees form an inverted-V shape in cross-section, and therefore, the cavities between these optical vees form a trapezoidal shape in cross-section.

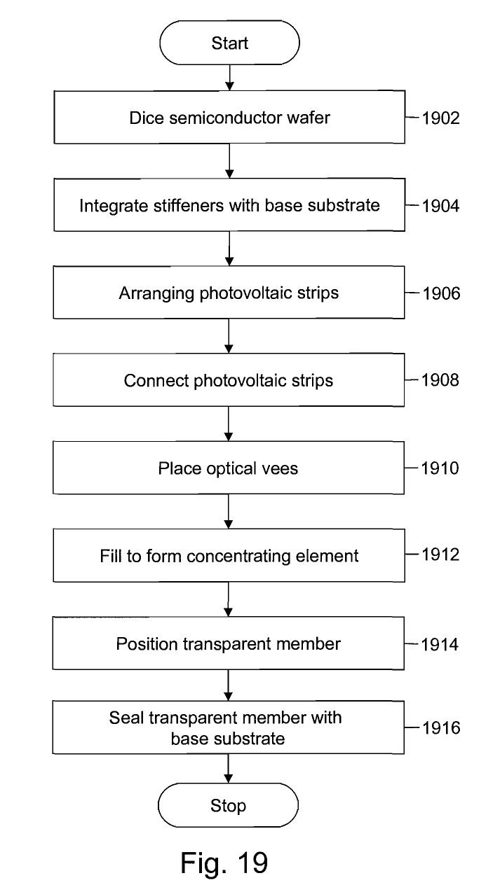

FIG. 19 is a flow diagram illustrating a method for fabricating a photovoltaic module, in accordance with another embodiment of the present invention. At step 1902, a semiconductor wafer is diced to form one or more photovoltaic strips. This can be accomplished by mechanical sawing or laser dicing. In laser dicing, a semiconductor wafer is diced from its base-side using a laser source. This provides a clean cut without any burrs, and involves minimal device damage. At step 1904, one or more stiffeners are integrated with base substrate. As mentioned earlier, the stiffeners are attached with at least one outer surface with base substrate, in an embodiment of the present invention. In another embodiment of the present invention, the base substrate and the stiffeners are integrated in a composite form. At step 1906, one or more photovoltaic strips are arranged over a base substrate in a predefined manner. The predefined manner may, for example, be a series and/or parallel arrangement, such that electrical output is maximized. At step 1908, the photovoltaic strips are connected through one or more conductors. This can be accomplished by manual soldering or high-speed soldering machine. In such a case, solder-coated copper strips may be used as the conductors. As mentioned above, the photovoltaic strips may be connected in series and/or parallel.

At step 1910, a plurality of optical vees are placed in the spaces between the photovoltaic strips, such that one or more cavities are formed between adjacent optical vees. As mentioned above, the optical vees may be placed in a manner that each photovoltaic strip has two adjacent optical vees. The optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. Depending on the shape and configuration of the photovoltaic strips, optical vees with a suitable shape may be used. For example, rectangular optical vees may be used for rectangular photovoltaic strips. In accordance with an embodiment of the present invention, these optical vees form an inverted-V-shape in cross-section, and therefore, the cavities between these optical vees form a trapezoidal shape in cross-section.

At step 1912, a polymeric material fills the cavities between the optical vees. These cavities enable moulding of the polymeric material, with space or air bubble left between the polymeric material and the photovoltaic strips, and between the polymeric material and the optical vees is minimized. These moulded concentrating elements concentrate solar energy over the photovoltaic strips. As mentioned above, the polymeric material can be any material that is tolerant to moisture, UV radiation, abrasion, and natural temperature variations.

At step 1914, a transparent member is positioned coupled over the moulded concentrating elements. The transparent member is optically coupled to the moulded concentrating elements. The transparent member is optically transparent, and protects the moulded concentrating elements and the photovoltaic strips from environmental damage, while allowing electromagnetic radiation falling on its surface to pass to the moulded concentrating elements. It is desirable that the polymeric material has properties suitable for adhesion to glass. The refractive index of the polymeric material may, for example, be 1.5 or above. Examples of the polymeric material include, but are not limited to, EVA, silicone, TPU, PVB, acrylics, polycarbonates, and synthetic resins. The transparent member may, for example, be a toughened glass with low iron content, or be made of a polymeric material.

In order to increase the efficiency of concentration, various parameters, such as the reflectivity of the transparent member, and the refractive indices of the transparent member and the moulded concentrating elements, may be manipulated. For example, the transparent member may be coated with an anti-reflective coating to reduce loss of solar energy incident on the photovoltaic module. In such a case, no reflection occurs at a medium boundary between air and the transparent member, thereby increasing the efficiency of concentration. In addition, no refraction occurs at a medium boundary between the transparent member and the moulded concentrating elements when the refractive index of the transparent member is equal to the refractive index of the moulded concentrating elements. In such a case, the medium boundary between the transparent member and the moulded concentrating elements is optically transparent. Rays incident on the medium boundary refract with an angle of refraction smaller than an angle of incidence when the refractive index of the transparent member is less than the refractive index of the moulded concentrating elements. At step 1916, the transparent member is sealed with the base substrate.

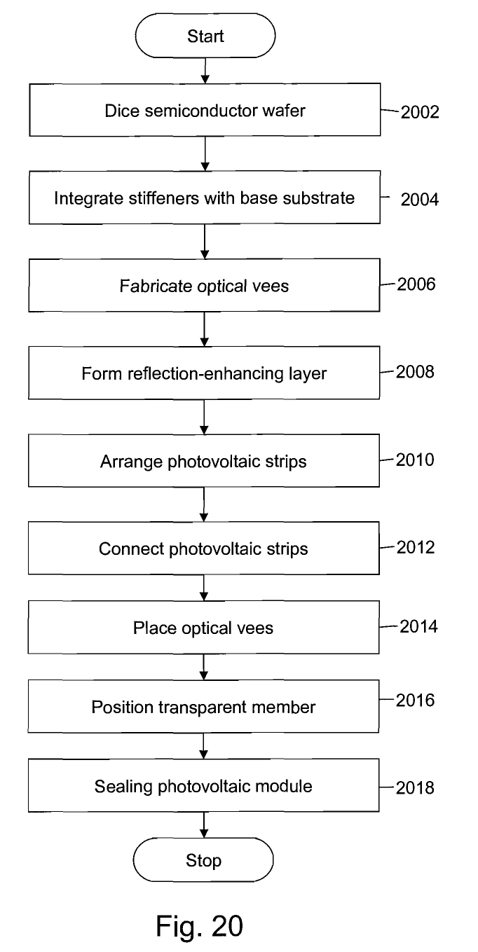

FIG. 20 is a flow diagram illustrating a method for fabricating a photovoltaic module, in accordance with another embodiment of the present invention. At step 2002, a semiconductor wafer is diced to form one or more photovoltaic strips. At step 2004, one or more stiffeners are integrated with base substrate. At step 2006, fabrication of optical vees takes place. The optical vees fabrication may be done in different ways. In an example, solid blocks of a reflective material may be machined to form the optical vees or surfaces of each solid block may be polished to form a reflective layer. In another example, a sheet of a reflective material may be polished to form a reflective layer or the polished sheet may be bent to form at least one of the optical vees. In yet another example, a foil of a reflective material may be sandwiched between two sheets to form a sandwiched foil and the sandwiched foil forms the reflective layer or the sandwiched foil may be bent to form at least one of the optical vees. In still another example, a polymeric material may be moulded to form the optical vees or a reflective material may be deposited over the optical vees to form a reflective layer. At step 2008, a reflection-enhancing layer is formed over the optical vees to enhance the reflectivity of the optical vees.

At step 2010, one or more photovoltaic strips are arranged over a base substrate in a predefined manner. The predefined manner may, for example, be a series and/or parallel arrangement, such that electrical output is maximized. At step 2012, the photovoltaic strips are connected through one or more conductors. This may be accomplished by manual soldering or by soldering using a high-speed soldering machine. Solder-coated copper strips may, for example, be used as the conductors. As mentioned above, the photovoltaic strips may be connected in series and/or parallel.

At step 2014, a plurality of optical vees are placed in the spaces between the photovoltaic strips, such that solar energy is concentrated over the optical vees. As mentioned above, the optical vees have a reflective layer, and may be either hollow or solid. At step 2018, the photovoltaic strips and the optical vees are sealed with the transparent member.

In an embodiment of the present invention, the transparent member is sealed around the corners to the base substrate, using a suitable material. This may be accomplished by a resistive heating process using sealing rollers that melts a solder preform and forms a hermetic seal. The seal may also be formed by a needle-dispensed epoxy, gasket sealing, glass frit, or EVA. As the seal at the edge of the photovoltaic module so formed may remain non-hermetic, an additional step of framing the photovoltaic module may be performed. This can be accomplished by mechanically attaching a frame to the photovoltaic module. The frame may be made of a metal or a metallic alloy. Aluminium may be used for this purpose, as it is cheaper and lighter than other metals and metallic alloys.

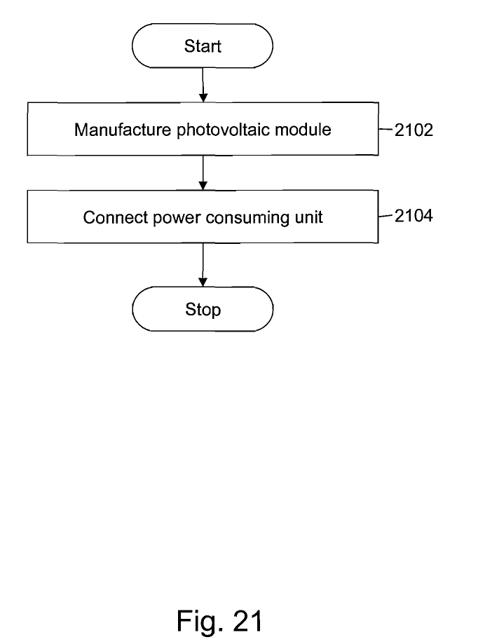

FIG. 21 illustrates a method for manufacturing a system for generating electricity from solar energy, in accordance with an embodiment of the present invention.

At step 2102, a photovoltaic module is manufactured as described in FIGS. 9a, 9b, 10a, 10b, 11, 12, 18, 19 and 20. The photovoltaic module may be similar to photovoltaic modules 900a and 900b. At step 2104, a power-consuming unit is connected to the photovoltaic module. The power-consuming unit consumes and/or stores the charge generated by the photovoltaic module. Examples of the power-consuming unit may include a battery or a utility grid. The power-consuming unit may be used to supply power to various devices.

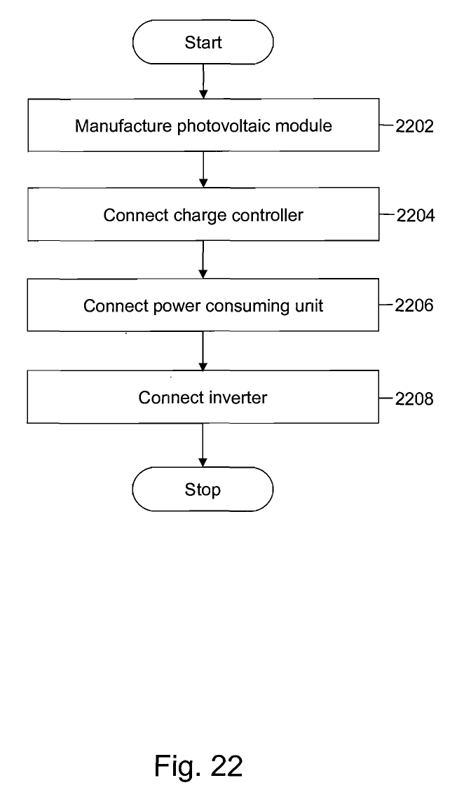

FIG. 22 illustrates a method for manufacturing a system for generating electricity from solar energy, in accordance with another embodiment of the present invention.

At step 2202, a photovoltaic module is manufactured as described in FIGS. 9a, 9b, 10a, 10b, 11, 12, 18, 19 and 20. At step 2204, a charge controller is connected with the photovoltaic module. At step 2206, a power-consuming unit is connected to the charge controller. The charge controller controls the amount of charge stored in the power-consuming unit. For example, if the amount of charge stored in the power-consuming unit exceeds a predefined value of the charge stored in the power-consuming unit, the charge controller disconnects the further charging of the power-consuming unit by the photovoltaic module. Further, if the charge stored in the power-consuming unit decreases to a threshold value it starts charging of the power-consuming unit. In an embodiment of the present invention, the predefined value and the threshold value are between the minimum and the maximum capacity of consuming charge in the power-consuming unit.

The power-consuming unit provides the electricity in the first form. The devices that use the first form of electricity may directly be connected to the power-consuming unit. However, if the devices don't use the first form of electricity, as generated by the power-consuming unit, at step 2208, an inverter is connected with the power-consuming unit. The inverter converts the electricity from a first form, as stored in the power-consuming unit, to a second form. Examples of the first form and the second form include the direct current and the alternate current.

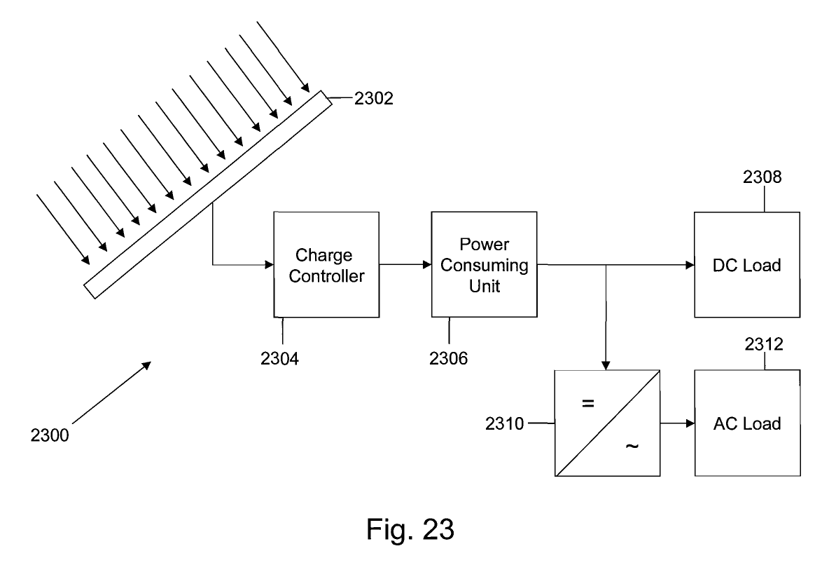

FIG. 23 illustrates a system 2300 for generating electricity from solar energy, in accordance with an embodiment of the present invention. System 2300 includes a photovoltaic module 2302, a charge controller 2304, a power-consuming unit 2306, a Direct Current (DC) load 2308, an inverter 2310 and an Alternating Current (AC) load 2312.

Photovoltaic module 2302 generates electricity from the solar energy that falls on photovoltaic module 2302. Photovoltaic module 2302 is similar to photovoltaic modules 900a and 900b. Power-consuming unit 2306 is connected with photovoltaic module 2302. Power-consuming unit 2306 consumes the charge generated by photovoltaic module 2302.

In an embodiment of the present invention, power-consuming unit 2306 stores the charge generated by photovoltaic module 2302. Power-consuming unit 2306 may, for example, be a battery. In an embodiment of the present invention, charge controller 2304 is connected with photovoltaic module 2302 and power-consuming unit 2306. Charge controller 2304 controls the amount of charge stored in power-consuming unit 2306. For example, if charge stored in power-consuming unit 2306 exceeds a first threshold, charge controller 2304 disconnects further storing of charge generated by photovoltaic module 2302 on to power-consuming unit 2306. Similarly, if charge stored in power-consuming unit 2306 falls below a second threshold, charge controller 2304 reinitiates storing of charge from photovoltaic module 2302 on to power-consuming unit 2306. In an embodiment of the present invention, the first threshold and the second threshold lie between the maximum and the minimum capacity of power-consuming unit 2306.

Power-consuming unit 2306 produces electricity in a first form. In an embodiment of the present invention, the first form is a DC that can be utilized by DC load 2308. DC load 2308 may, for example, be a device that operates on DC. In another embodiment of the present invention, the first form is an AC that can be utilized by AC load 2312. AC load 2312 may, for example, be a device that operates on AC.

Inverter 2310 is connected with power-consuming unit 2306. Inverter 2310 converts electricity from the first form to a second form, as required. The second form may be either DC or AC. Consider, for example, that the first form is DC, and a device requires electricity in the second form, that is, AC. Inverter 2310 converts DC into AC.

System 2300 may be implemented at a roof top of a building, for home or office use. Alternatively, system 2300 may be implemented for use with stand-alone electrical devices, such as automobiles and spacecraft.

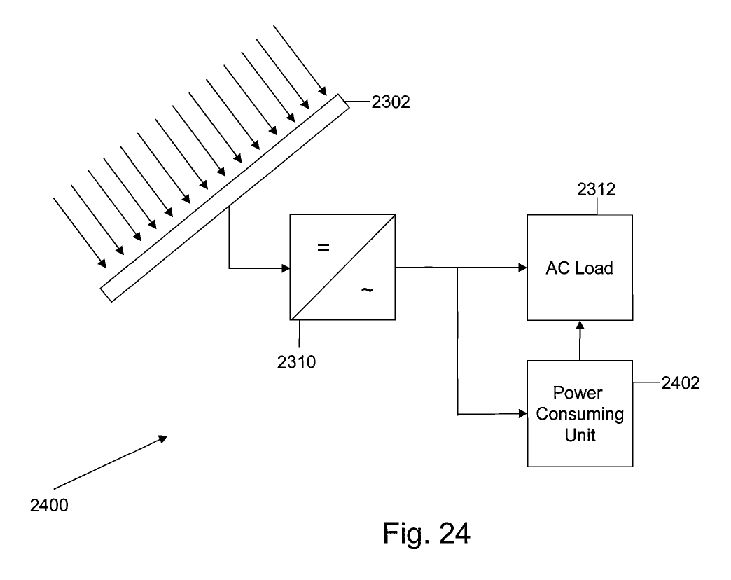

FIG. 24 illustrates a system 2400 for generating electricity from solar energy, in accordance with another embodiment of the present invention. System 2400 includes photovoltaic module 2302, a power-consuming unit 2402, inverter 2310 and AC load 2312.

As mentioned above, inverter 2310 converts electricity generated by photovoltaic module 2402 from the first form to the second form. With reference to FIG. 24, electricity in the second form is utilized by power-consuming unit 2402. Power-consuming unit 2402 may, for example, be a utility grid. For example, an array of photovoltaic modules 2402 may be used to generate electricity on a large scale for grid power supply.

Embodiments of the present invention provide a photovoltaic module that is suitable for mass manufacturing, has lower cost, and is easy to manufacture compared to conventional low concentrator photovoltaic modules. The photovoltaic module has the same form factor as conventional photovoltaic modules, and therefore, has no special mounting requirements. In addition, the fabrication of the photovoltaic module involves the same processes as well as machines as required for fabricating existing flat photovoltaic modules with optical vees and moulded concentrating elements.

Further, moulded concentrating elements are not formed separately, and are rather formed by pouring a suitable polymeric material over photovoltaic strips and optical vees. This minimizes optical defects, such as void spaces and air bubbles within the photovoltaic module, while quickening the process of fabrication.

Furthermore, the photovoltaic module provides maximized outputs, at appropriate configurations of the photovoltaic strips and appropriate levels of concentration. Moreover, the photovoltaic module is made of photovoltaic strips, which are arranged with spaces in between two adjacent photovoltaic strips. Therefore, the photovoltaic module requires lesser amount of semiconductor material to produce the same output, as compared to conventional low concentrator photovoltaic modules.

1. An electronic substrate for use in a photovoltaic module, said electronic substrate comprising:
a base for providing a plurality of path options;
one or more conductive pads formed over said base, such that pad spaces are created between adjacent conductive pads, said conductive pads configured to receive one or more photovoltaic strips, wherein said conductive pads are electrically connected with at least one of said path options; and
one or more bond pads formed over said base, wherein said bond pads provide an interface to connect said photovoltaic strips to said path options in a predefined manner.

2. The electronic substrate of claim 1 further comprising one or more connectors for connecting said photovoltaic strips to said bond pads.

3. The electronic substrate of claim 1, wherein said pad spaces are configured to receive one or more optical vees for concentrating solar energy over said photovoltaic strips.

4. The electronic substrate of claim 1, wherein the predefined manner is a series and/or parallel arrangement.

5. The electronic substrate of claim 1, wherein said base is selected from the group consisting of a printed circuit board (PCB) and a hybrid microcircuit.

6. A photovoltaic module for generating electricity from solar energy, said photovoltaic module comprising:
an electronic substrate for providing support to said photovoltaic module, said electronic substrate comprising:
a base for providing a plurality of path options;
one or more conductive pads formed over said base, such that pad spaces are created between adjacent conductive pads, said conductive pads being electrically connected with at least one of said path options; and
one or more bond pads formed over said base;
one or more photovoltaic strips arranged over said conductive pads, said photovoltaic strips being capable of converting solar energy into electrical energy, wherein said bond pads provide an interface to connect said photovoltaic strips to said path options in a predefined manner;
one or more optical vees placed over said pad spaces, such that a plurality of cavities is formed between adjacent optical vees, wherein said optical vees are capable of concentrating solar energy over said photovoltaic strips; and
one or more connectors for connecting said photovoltaic strips to said bond pads.

7. The photovoltaic module of claim 6, wherein said optical vees comprise a reflective layer or surface, such that rays incident on said reflective layer or surface are reflected towards said photovoltaic strips.

8. The photovoltaic module of claim 7, wherein said optical vees comprise a polymeric material, and said reflective layer or surface comprises a reflective material.

9. The photovoltaic module of claim 7, wherein said reflective layer or surface comprises a polished sheet of a reflective material.

10. The photovoltaic module of claim 7, wherein said reflective layer or surface comprises a sandwiched foil comprising a foil of a reflective material between two sheets.

11. The photovoltaic module of claim 6, wherein said optical vees are hollow.

12. The photovoltaic module of claim 6, wherein said optical vees are solid.

13. The photovoltaic module of claim 6, wherein said optical vees further comprise:
a first medium;
a second medium, said second medium underlying said first medium such that a ratio of a refractive index of said first medium to a refractive index of said second medium is greater than one.

14. The photovoltaic module of claim 6 further comprising one or more concentrating elements, said concentrating elements being capable of concentrating solar energy over said photovoltaic strips.

15. The photovoltaic module of claim 14, wherein said concentrating element comprises a polymeric material that has the shape of said cavities.

16. The photovoltaic module of claim 14, wherein said concentrating element comprises re-molded concentrating elements.

17. The photovoltaic module of claim 14, wherein said concentrating element is a pre-molded concentrating element.

18. The photovoltaic module of claim 14, wherein the refractive indices of said concentrating element and said optical vees are more than the refractive index of air or vacuum.

19. The photovoltaic module of claim 6 further comprising a transparent member positioned over said optical vees.

20. An apparatus for generating electricity from solar energy, said apparatus comprising:
supporting means for providing support to said apparatus, wherein said supporting means provides a plurality of path options;
padding means for providing a conductive path, said padding means formed over said supporting means, such that pad spaces are created between adjacent padding means, said padding means being electrically connected to at least one of said path options;
converting means for converting solar energy into electrical energy, said converting means being arranged over said padding means;
interfacing means for providing an interface to connect said converting means to said path options in a predefined manner, said interfacing means being formed over said supporting means;
concentrating means for concentrating solar energy over said converting means; and
connecting means for connecting said converting means to said interfacing means.

21.-108. (canceled)
